(19) United States
(12) Patent Application Publication
(10) Pub. No.: US 2023/0043434 A1
(43) Pub. Date: Feb. 9, 2023

(54) SEMICONDUCTOR DEVICE MANUFACTURING METHOD

(71) Applicant: FUJI ELECTRIC CO., LTD., Kanagawa (JP)

(72) Inventor: Masayuki MOMOSE, Matsumoto-city (JP)

(21) Appl. No.: 17/844,732

(22) Filed: Jun. 21, 2022

(30) Foreign Application Priority Data
Aug. 3, 2021 (JP) 2021-127405

(51) Int. Cl. H01L 21/322

(52) U.S. Cl. CPC H01L 21/3225

(57) ABSTRACT

Provided is a semiconductor device manufacturing method comprising: forming an impurity region including a first impurity on a semiconductor wafer; annealing the semiconductor wafer in a state where a lower surface of the semiconductor wafer is supported; and removing at least a part of the impurity region by removing a region including the lower surface of the semiconductor wafer. The first impurity may be oxygen. After the annealing, a maximum value of a concentration of the first impurity in the impurity region may be equal to or greater than 1×10¹⁸/cm³.

The contents of the following Japanese patent application are incorporated herein by reference:

No. 2021-127405 filed in JP on Aug. 3, 2021.

### BACKGROUND

### 1. Technical Field

The present invention relates to a manufacturing method of a semiconductor device.

### 2. Related Art

Conventionally, forming a semiconductor device by using a semiconductor wafer made of silicon or the like is known (For example, see Patent Document 1-3).
Patent Document 1: Japanese Patent Application Publication No. H5-62867
Patent Document 2: Japanese Patent Application Publication No. H9-190954
Patent Document 3: Japanese Patent Application Publication No. 2005-64524

### BRIEF DESCRIPTION OF THE DRAWINGS

FIG. 1 shows a process for annealing a semiconductor wafer 100.

FIG. 2 is an enlarged view of the region A in FIG. 1.

FIG. 3 illustrates one embodiment of the present invention.

FIG. 4 is a flowchart showing an example of a manufacturing method of a semiconductor device.

FIG. 5 illustrates a region forming step S410, an upper surface side structure forming step S420, and an annealing step S430.

FIG. 6 illustrates a removing step S440 and a lower surface side structure forming step S450.

FIG. 7 shows an example of impurity concentration distribution in a depth direction of a semiconductor wafer 100.

FIG. 8 shows another example of impurity concentration distribution in a depth direction of an impurity region 140.

FIG. 9 illustrates another example of the region forming step S410.

FIG. 10 illustrates another example of the region forming step S410, the upper surface side structure forming step S420, and the annealing step S430.

FIG. 11 illustrates another example of the removing step S440 and the lower surface side structure forming step S450.

### DESCRIPTION OF EXEMPLARY EMBODIMENTS

Hereinafter, the invention will be described through embodiments of the invention, but the following embodiments do not limit the invention according to claims. In addition, not all the combinations of features described in the embodiments are necessarily essential for a solution of the invention.

In the present specification, one side in a direction parallel to a depth direction of a semiconductor wafer is referred to as an “upper” side, and the other side is referred to as a “lower” side. One surface of two principal surfaces of a wafer, a substrate, a layer or another member is referred to as an upper surface, and the other surface is referred to as a lower surface. “Upper” and “lower” directions are not limited to a direction of gravity, or a direction in which a semiconductor device is mounted.

In the present specification, technical matters may be described by using orthogonal coordinate axes of an X axis, a Y axis and a Z axis. The orthogonal coordinate axes merely specify relative positions of components, and do not limit a specific direction. For example, the Z axis does not limit the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, the orthogonal axes which are parallel to an upper surface and a lower surface of a semiconductor wafer are referred to as an X axis and a Y axis. In addition, an axis which is perpendicular to the upper surface and the lower surface of the semiconductor wafer is referred to as a Z axis. In the present specification, the direction of the Z axis may be referred to as the depth direction. In addition, in the present specification, a direction parallel to the upper surface and the lower surface of the semiconductor wafer, including the X axis and the Y axis, may be referred to as a horizontal direction.

In addition, a region from the center of the depth direction of the semiconductor wafer to the upper surface thereof may be referred to as an upper surface side of the semiconductor wafer. Similarly, a region from the center of the depth direction of the semiconductor wafer to the lower surface thereof may be referred to as a lower surface side of the semiconductor wafer.

In the present specification, a case where a term such as “same” or “equal” is mentioned may include a case where an error due to a variation in manufacturing or the like is included.

The error is, for example, within 10%.

When charged particle such as an ion or electron is implanted into the semiconductor wafer with predetermined acceleration energy, the particle has a predetermined distribution in the depth direction. In the present specification, a position of a peak of the distribution may be referred to as a particle implantation position or implantation depth or the like.

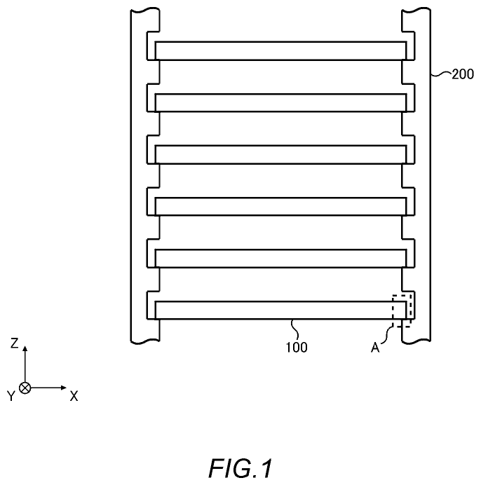

FIG. 1 is a diagram showing an example of a manufacturing step of a semiconductor device. The semiconductor device includes a semiconductor element such as a transistor or diode. The semiconductor device is formed on a semiconductor wafer 100. The semiconductor wafer 100 is formed of a semiconductor material such as silicon, silicon carbide or gallium nitride. The semiconductor wafer 100 has a disc-shape in a top view in a Z axis direction, for example. In FIG. 1, the semiconductor wafer 100 has a rectangular shape in a cross-sectional view in a Y axis direction, for example. In FIG. 1, an end portion of the semiconductor wafer 100 is not chamfered; but the end portion of the semiconductor wafer 100 may be chamfered. A plurality of semiconductor devices (semiconductor chips) may be formed on the semiconductor wafer 100. By dicing and singulating the semiconductor wafer 100, the plurality of semiconductor devices can be manufactured.

FIG. 1 shows a process for annealing a semiconductor wafer 100. For example, in the manufacturing step of the semiconductor device, the semiconductor wafer 100 may be annealed at a predetermined temperature for a predetermined time after implanting an impurity into the semiconductor wafer 100. By annealing the semiconductor wafer 100, the impurity can be spread and also activated as a donor or an acceptor. When annealing the semiconductor wafer 100, a carrying boat 200 in which the semiconductor wafer 100 is placed is input into an annealing furnace. In the carrying boat 200, a plurality of semiconductor wafers 100 may be placed.

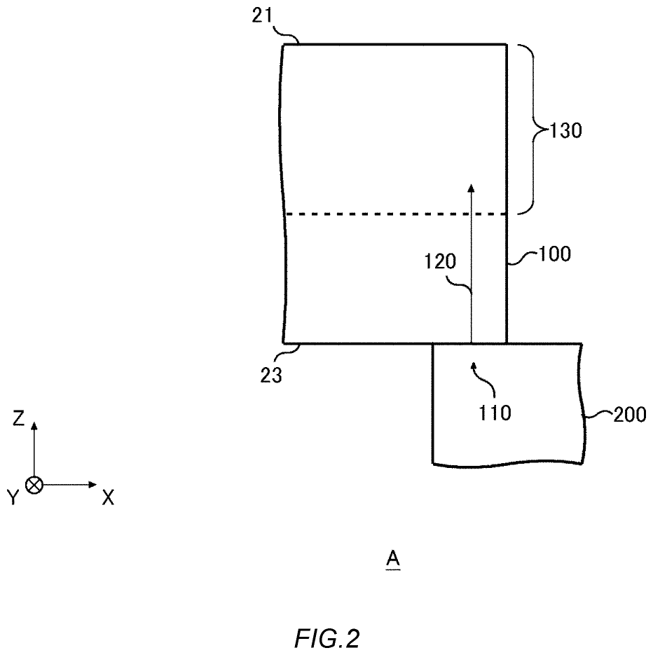

FIG. 2 is an enlarged view of the region A in FIG. 1. The region A includes a portion in which the semiconductor wafer 100 and the carrying boat 200 are contacting each other. The semiconductor wafer 100 has an upper surface 21 and a lower surface 23. The upper surface 21 and the lower surface 23 are two principal surfaces of the semiconductor wafer 100. That is, the upper surface 21 and the lower surface 23 are the two surfaces having the largest areas in the semiconductor wafer 100.

In the semiconductor wafer 100 of the present example, at least part of the lower surface 23 is supported by the carrying boat 200. A portion of the lower surface 23 of the semiconductor wafer 100, which contacts the carrying boat 200, is referred to as a supporting portion 110. In the present example, an end portion of the lower surface 23 of the semiconductor wafer 100 is contacting the carrying boat 200, but the entire lower surface 23 of the semiconductor wafer 100 may contact the carrying boat 200.

In a state where the lower surface 23 of the semiconductor wafer 100 is supported, stress is generated nearby the supporting portion 110 due to the semiconductor wafer 100's own weight. If the semiconductor wafer 100 is annealed in this state, a defect may be generated on the supporting portion 110. In the present specification, the defect is referred to as a slip 120. The defect is a distortion of crystal structure in the semiconductor wafer 100 (that is, a crystal defect). As shown by an arrow in FIG. 2, the slip 120 proceeds in a direction from the supporting portion 110 towards the upper surface 21.

The semiconductor wafer 100 includes an element region 130 in which a semiconductor element is formed. The element region 130 in the present example is contacting the upper surface 21 of the semiconductor wafer 100. The element region 130 is a region from the semiconductor wafer 100, which remains without being removed when a semiconductor device is formed. The regions other than the element region 130 in the semiconductor wafer 100 are removed in the manufacturing step. For example, the semiconductor wafer 100 is formed to be thicker than a semiconductor substrate of a semiconductor device to be finally manufactured, in order to prevent damage or the like in the manufacturing step. In the final stage of the manufacturing step, the thickness of the semiconductor wafer 100 is adjusted according to a breakdown voltage or the like of the semiconductor device. For example, by grinding the lower surface 23 side of the semiconductor wafer 100, the thickness of the semiconductor wafer 100 is adjusted. In FIG. 1 and FIG. 2, the semiconductor wafer 100 before adjusting the thickness is shown.

If the above-described slip 120 reaches the element region 130, it affects the characteristic of the semiconductor element. For example, effects such as an increase of leakage current of the semiconductor element, and a decrease of the breakdown voltage may occur. As the annealing temperature becomes higher, the slip 120 is more likely to be generated and to proceed. In particular, if the annealing temperature becomes high to be equal to or greater than 1000° C., the generation of the slip 120 becomes significant, and the slip 120 is likely to reach the element region 130.

On the other hand, in the manufacturing step of the semiconductor device, a case where the semiconductor wafer 100 is annealed at a high temperature is considered. For example, the annealing temperature increases when the impurity which is implanted into the element region 130 of the semiconductor wafer 100 is spread to a position which is apart from the implantation position. In such a case, the slip 120 is likely to reach the element region 130. The generation and development of the slip 120 can be suppressed by annealing at a low temperature, but in such a case the annealing time becomes longer if the impurity is to be sufficiently spread and thus a throughput of the manufacturing step decreases.

In addition, if a diameter of the semiconductor wafer 100 is equal to or greater than approximately 300 mm, the generation of the slip 120 becomes significant, and the slip 120 is likely to reach the element region 130. This is considered to be caused because the semiconductor wafer 100's own weight increases and thus the stress nearby the supporting portion 110 increases.

In addition, if an oxygen concentration originally included in the semiconductor wafer 100 is equal to or less than 8×10′⁷/cm³, the generation of the slip 120 becomes significant, and the slip 120 is likely to reach the element region 130. This is considered to be caused because the slip 120 becomes likely to proceed due to the decrease of the oxygen concentration.

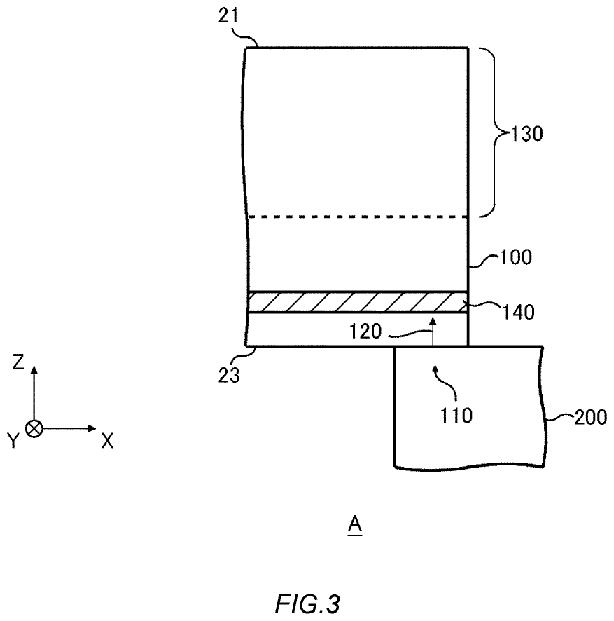

FIG. 3 illustrates one embodiment of the present invention. In the present example, before a process in which the semiconductor wafer 100 is annealed at a high temperature (for example, equal to or greater than 1000° C.), an impurity region 140 is formed in advance including a first impurity in the semiconductor wafer 100. In the present specification, an impurity which forms the impurity region 140 is referred to as a first impurity. The impurity region 140 is positioned at a lower surface 23 side of the semiconductor wafer 100. The lower surface 23 side refers to a region between the center in a depth direction of the semiconductor wafer 100 and the lower surface 23. The impurity region 140 is a region where an atomic concentration of the first impurity per unit volume (atoms/cm³) is locally higher than the other regions. In the present specification, an atomic concentration of the impurity per unit volume may be simply referred to as an impurity concentration (/cm³). The impurity concentration can be measured with a well-known method such as the SIMS method (Secondary Ion Mass Spectrometry), for example.

The development of slip 120 which has reached from the lower surface 23 to the impurity region 140 is suppressed by the first impurity included in the impurity region 140. It is considered that, for example, if the slip 120 which has developed within the silicon crystal contacts the first impurity, the slip cannot bypass the first impurity and thus the development of the slip 120 towards the upper surface 21 side is suppressed. In this way, the impurity region 140 suppresses the development of the slip 120 from the lower surface 23 which is to be closer to the upper surface 21 side than the impurity region 140.

The first impurity included with a high concentration in the impurity region 140 is oxygen, for example. Note that the first impurity is not limited to oxygen. As the first impurity, an element which can suppress or inhibit the development of the slip 120 may be used. The first impurity may be nitrogen, may be hydrogen, carbon, or may be another element. The first impurity is an element different from the semiconductor material which forms the semiconductor wafer.

At least a part of the impurity region 140 is preferred to be positioned closer to the lower surface 23 side than the element region 130. In this way, the reaching of the slip 120 to the element region 130 can be suppressed. The entire impurity region 140 may be positioned closer to the lower surface 23 side than the element region 130, or a part thereof may be positioned on the element region 130.

The impurity region 140 may be positioned to be overlapped with at least the supporting portion 110 in an X-Y plane which is parallel to the lower surface 23. The impurity region 140 may be positioned on the entire semiconductor wafer 100 in the X-Y plane. That is, the impurity region 140 may be positioned to be overlapped with the entire surface of the lower surface 23.

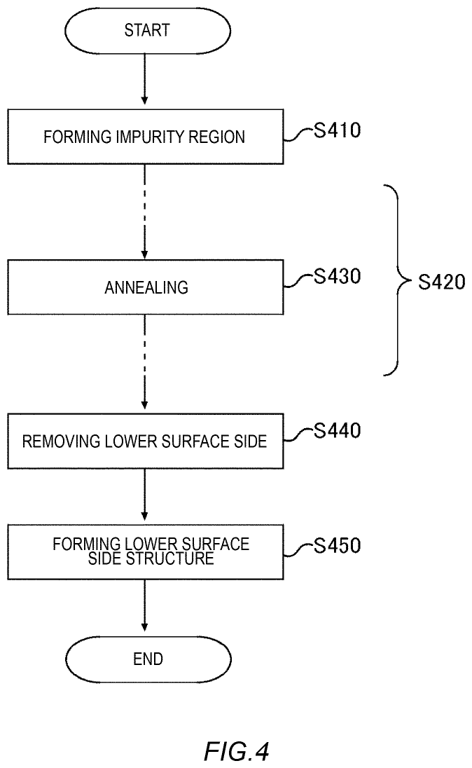

FIG. 4 is a flowchart showing an example of a manufacturing method of a semiconductor device. The manufacturing method of the present example includes a region forming step S410, an annealing step S430 and a removing step S440. The manufacturing method may further include an upper surface side structure forming step S420 and a lower surface side structure forming step S450. The annealing step S430 of the present example is included in the upper surface side structure forming step S420.

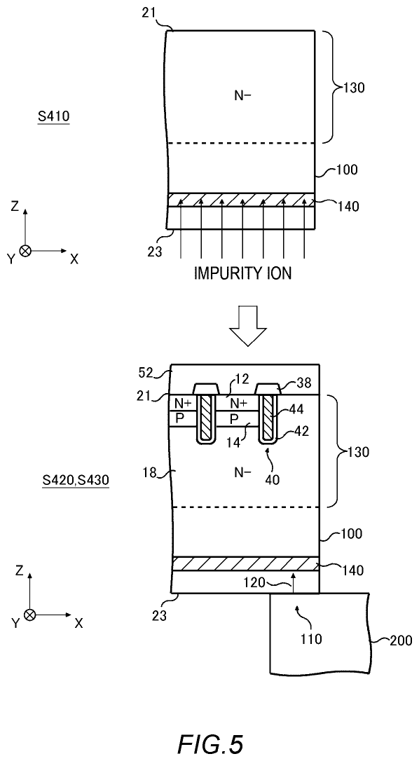

FIG. 5 illustrates a region forming step S410, an upper surface side structure forming step S420, and an annealing step S430. A description of each step in FIG. 5 and the like shows a structure nearby the region A. The semiconductor wafer 100 of the present example is an N—type wafer. That is, a donor such as phosphorous is approximately uniformly distributed on the entire semiconductor wafer 100 immediately after a cut out from an ingot. In the present specification, a donor which is approximately uniformly distributed on the entire initial semiconductor wafer 100 may be referred to as a bulk donor.

In the region forming step S410, an impurity region 140 is formed on the lower surface 23 side of the semiconductor wafer 100. In the present example, the impurity region 140 is formed by implanting an ion of a first impurity such as an oxygen ion from the lower surface 23 of the semiconductor wafer 100. The ion of the first impurity may be implanted from the entire surface of the lower surface 23. In this case, the impurity region 140 is formed on the entire surface to be overlapped with the entire lower surface 23 at a predetermined depth position from the lower surface 23. In another example, the impurity region 140 may be formed by an epitaxial deposition. In addition, the semiconductor wafer 100 may be formed by adhering a wafer in which the impurity region 140 is formed on a surface thereof with a wafer including the element region 130 together.

Subsequently, in the upper surface side structure forming step S420, at least a partial structure (may be referred to as an upper surface side structure) of the semiconductor element is formed closer to an upper surface 21 side than the impurity region 140. The semiconductor element of the present example is a trench gate type transistor. The upper surface side structure of the present example includes an emitter region 12, a base region 14, and a gate trench 40. In FIG. 5, the upper surface side structure is schematically shown. The emitter region 12 is an N+type region provided to contact the upper surface 21 of the semiconductor wafer. The base region 14 is a P type region provided below the emitter region 12. An N—type drift region 18 is provided below the base region 14. An impurity concentration of the drift region 18 may be approximately the same as a concentration of the bulk donor. That is, the drift region 18 may be a region remaining without having the regions such as the emitter region 12 and the base region 14 formed thereon.

The gate trench 40 is provided from the upper surface 21 of the semiconductor wafer 100 to reach the drift region 18. The gate trench 40 includes a gate electrode 44 and a gate insulating film 42. The gate electrode 44 is formed of a conductive material such as polysilicon doped with an impurity. The gate insulating film 42 is provided between the gate electrode 44 and the semiconductor wafer 100 to electrically insulate the two. The gate insulating film 42 is an oxide film, for example. The emitter region 12 and the base region 14 are contacting a side surface of the gate trench 40. If a predetermined gate voltage is applied to the gate electrode 44, the base region 14 at a boundary with the gate trench 40 is inverted into the N type to form a channel. In this way, current flows between the emitter region 12 and the drift region 18. That is, the transistor becomes ON state.

The upper surface side structure may include an interlayer dielectric film 38 and an emitter electrode 52. The emitter electrode 52 is an electrode including a metal such as aluminum. The emitter electrode 52 is connected to the emitter region 12. The interlayer dielectric film 38 electrically insulates the gate electrode 44 and the emitter electrode 52 from each other. The interlayer dielectric film 38 may be provided on the upper surface 21 of the semiconductor wafer 100 to cover the gate trench 40.

The emitter region 12 and the base region 14 may be formed by implanting an impurity into the semiconductor wafer 100 and performing an annealing process. The annealing process may correspond to the annealing step S430. The annealing process may be performed by using the carrying boat 200.

As described above, in the annealing step S430, the slip 120 may be generated on the lower surface 23 of the semiconductor wafer 100. In the present example, even if the slip 120 is generated, the development of the slip 120 can be suppressed by the impurity region 140. Thus, the development of the slip 120 to the element region 130 can be suppressed.

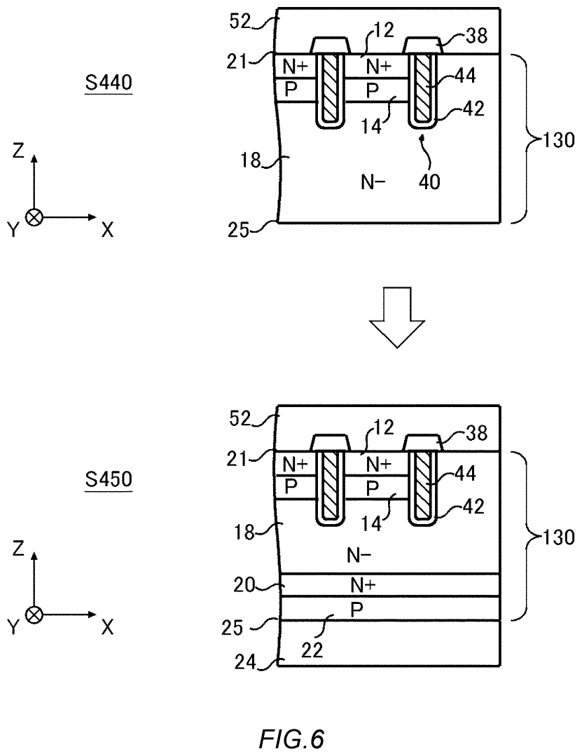

FIG. 6 illustrates a removing step S440 and a lower surface side structure forming step S450. In the removing step S440, regions including the lower surface 23 of the semiconductor wafer 100 are removed. In the present example, the lower surface 23 of the semiconductor wafer 100 is grinded by a method such as CMP. In the removing step S440, at least a part of the impurity region 140 is removed. For example, the lower surface 23 side of the semiconductor wafer 100 is grinded until it reaches inside of at least the impurity region 140. In this way, the region where the slip 120 is generated can be removed. In the example of FIG. 6, the entire impurity region 140 is removed. That is, the semiconductor wafer 100 is grinded closer to the upper surface 21 side than the impurity region 140. After performing the removing step S440, the semiconductor wafer 100 includes the lower surface 25. The lower surface 25 is positioned closer to the upper surface 21 side than the lower surface 23.

In the lower surface side structure forming step S450, after the removing step S440, at least a partial structure (referred to as a lower surface side structure) of the semiconductor element is formed on the lower surface 25 side of the semiconductor wafer 100. The semiconductor element shown in FIG. 6 is an IGBT (Insulated Gate Bipolar Transistor). The lower surface side structure of the present example includes a collector region 22 and a collector electrode 24. The lower surface side structure may further include a buffer region 20. The collector region 22 is a P type region provided to contact the lower surface 25. The collector electrode 24 is an electrode provided on the lower surface 25, which includes a metal such as aluminum. By the gate voltage applied to the gate electrode 44, whether to flow current between the emitter electrode 52 and the collector electrode 24 can be controlled. The buffer region 20 is an N type region provided between the drift region 18 and the collector region 22. A donor concentration of the buffer region 20 is higher than a donor concentration of the drift region 18. The buffer region 20 functions as a field stop layer configured to suppress a depletion layer which expands from a PN junction of the base region 14 and the drift region 18 from reaching the collector region 22.

According to the example described in FIG. 5 and FIG. 6, even the manufacturing step including the annealing step S430 with the high temperature can suppress the slip 120 from reaching the element region 130. Thus, a semiconductor device with little defect can be manufactured while increasing the throughput of the manufacturing step.

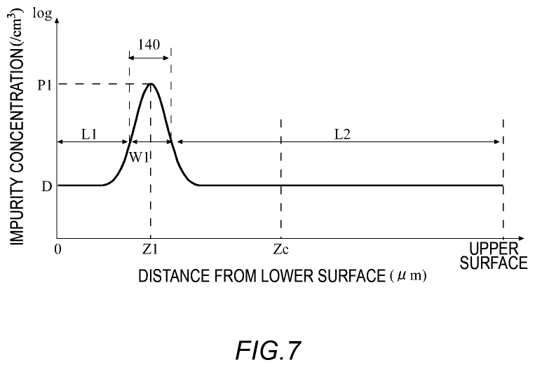

FIG. 7 shows an example of impurity concentration distribution in a depth direction of a semiconductor wafer 100. In FIG. 7, a concentration distribution of the first impurity implanted into the impurity region 140 such as oxygen is shown, and concentrations of other impurities are not included. In addition, in FIG. 7, a concentration distribution after the annealing step S430 is shown.

A maximum value of a first impurity concentration of the impurity region 140 is referred to as P1. In the present example, the impurity region 140 is formed by implanting the first impurity such as an oxygen ion into a depth position Z1. Thus, the impurity concentration distribution shows a peak having a local maximum on the depth position Z1. A maximum value P1 of the present example is a first impurity concentration at the local maximum of the peak.

The maximum value P1 is preferred to be equal to or greater than 1×10¹⁸/cm³. By setting the maximum value P1 to be equal to or greater than 1×10¹⁸/cm³, even if the annealing temperature is equal to or greater than 1000° C., the slip 120 can be suppressed from reaching the element region 130. The maximum value P1 may be equal to or greater than 5×10¹⁸/cm³, or may be equal to or greater than 1×10¹⁹/cm³.

Note that the first impurity such as oxygen may be distributed on the entire semiconductor wafer 100. For example, when an ingot of a semiconductor is formed, the first impurity is included in the entire ingot. Since the semiconductor wafer 100 is cut out from the ingot, the first impurity may be included in the entire semiconductor wafer 100. As an example, an entire semiconductor wafer 100 cut out from an ingot formed by the MCZ method includes oxygen equal to or less than 4×10¹⁷/cm³. In the present example, a concentration of the first impurity distributed in the entire semiconductor wafer 100 is referred to as D. The concentration D may be an average value of the concentration of the first impurity in the entire semiconductor wafer 100. The maximum value P1 may be equal to or greater than 5 times the concentration D, may be equal to or greater than 10 times the concentration D, or may be equal to or greater than 50 times the concentration D. The concentration D of the present example is equal to or less than 4×10¹⁷/cm³. For a semiconductor wafer which has not an impurity region 140 formed thereon and has an average concentration of oxygen equal to or less than 4×10¹⁷/cm³, the slip 120 was not able to be suppressed from proceeding.

Note that the concentration of the first impurity of the impurity region 140 may be less than 1×10²⁰/cm³. That is, the maximum value P1 may be less than 1×10²⁰/cm³. If the concentration of the first impurity of the impurity region 140 is too high, the first impurity may be spread to the element region 130 to affect the characteristic of the semiconductor device. The concentration of the first impurity of the impurity region 140 may be equal to or less than 5×10¹⁹/cm³ or may be equal to or less than 1×10¹⁹/cm³.

In the present example, a center position in the depth direction of the semiconductor wafer 100 is referred to as a depth position Zc. The depth position Z1 is positioned between the lower surface 23 and the depth position Zc. When the impurity is implanted by an ion implantation, the impurity concentration distribution has a peak with a local maximum nearby the depth position Z1. A range of full width at half maximum in a depth direction of the peak is referred to as a width W1 in a depth direction of the impurity region 140. The width W1 may be equal to or less than 100 μm. The impurity region 140 can obtain an effect of suppressing the development of the slip 120 even if it is not being formed in such a wide depth range. The width W1 may be equal to or less than 50 μm, may be equal to or less than 20 μm, or may be equal to or less than 10 μm. The width W1 may be equal to or greater than 1 μm, may be equal to or greater than 2 μm, may be equal to or greater than 5 μm. The width W1 may be equal to or less than 10%, may be equal to or less than 5%, or may be equal to or less than 1% of a thickness (a distance from the upper surface 21 to the lower surface 23) of the semiconductor wafer 100.

A distance between the impurity region 140 and the lower surface 23 is referred to as L1. The distance L1 may be equal to or less than 100 μm, may be equal to or less than 50 μm, or may be equal to or less than 20 μm. The distance L1 may be 0 μm. That is, the impurity region 140 may be exposed to the lower surface 23. By reducing the distance L1, a distance in a Z direction in which the slip 120 proceeds can be reduced.

A distance between the impurity region 140 and the upper surface 21 is referred to as L2. The distance L2 may be equal to or greater than 400 μm. By securing the distance L2, the element region 130 can be secured. The distance L2 may be equal to or greater than 200 μm. The distance L2 can be set by a thickness of the element region 130 to be formed. A distance between the element region 130 and the impurity region 140 may be equal to or greater than 0 μm, may be equal to or greater than 10 μm, or may be equal to or greater than 100 μm.

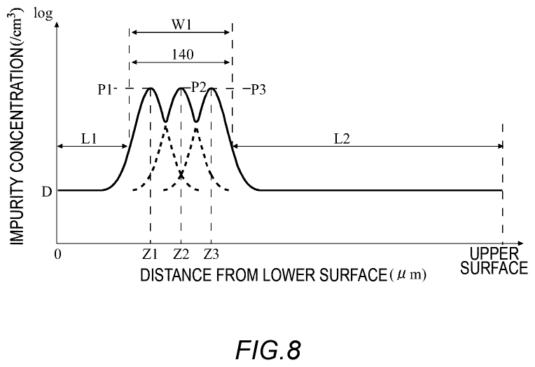

FIG. 8 shows another example of impurity concentration distribution in a depth direction of an impurity region 140. In the present example, by implanting the first impurity to a plurality of depth positions (for example, Z1, Z2, Z3), the impurity region 140 is formed. The other points are similar to the example of FIG. 7. According to the present example, the width W1 of the impurity region 140 is likely to be secured. Also, in addition to the effect of suppressing the development of the slip 120, the impurity region 140 may also have a gettering effect of capturing a nearby unnecessary component to combine with the first impurity. By securing the width W1, the gettering effect can be improved. The gettering effect is an effect of capturing and fixing the impurity which is present within the semiconductor wafer 100 and which causes a metal contamination or the like.

For example, depending on the type of impurity or acceleration energy of impurity ions, a case where a full width at half maximum of one concentration peak is small may be considered. In this case, the width W1 of the impurity region 140 also can be secured by implanting a first impurity ion to the plurality of depth positions. Concentration peaks of each depth position Z1, Z2, Z3 may be overlapped with each other, or may be apart from each other. The concentration peaks being apart from each other means that a concentration of a valley portion between two local maximums is less than half of a concentration at the local maximum. Each concentration P1, P2, P3 of the first impurity in each depth position Z1, Z2, Z3 may be the same or may be different. In addition, to each depth position Z1, Z2, Z3, a first impurity of a same element may be implanted, or a first impurity of different elements may be implanted. For example, oxygen may be implanted to each depth position Z1, Z2, Z3, or oxygen may be implanted to any depth position and then nitrogen may be implanted to another any depth position. By implanting the first impurity of different elements, the gettering effect can be obtained for various components.

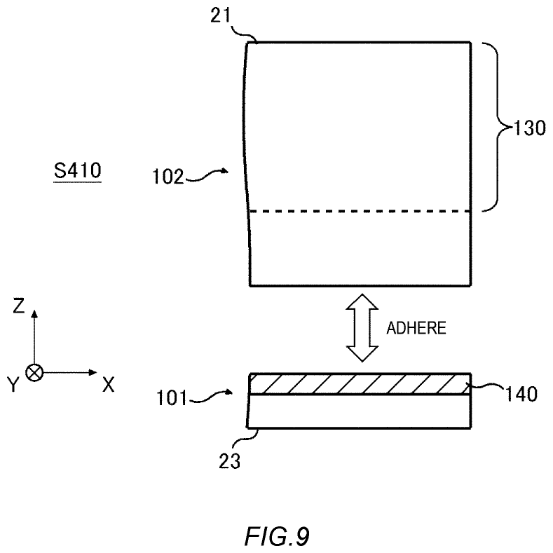

FIG. 9 illustrates another example of the region forming step S410. In the region forming step S410 of the present example, a semiconductor wafer 100 is formed by adhering a first wafer 101 in which an impurity region 140 formed together with a second wafer 102. Adhering of the wafers can be performed by using a well-known method.

The first wafer 101 has the impurity region 140 formed on its surface. The impurity region 140 may be formed by an ion implantation, or may be formed by an epitaxial deposition. In addition, the impurity region 140 may occupy the entire first wafer 101. That is, the first wafer 101 may include the first impurity such as oxygen in the entire wafer, with a high concentration. The second wafer 102 may include an element region 130 in which a semiconductor element is to be formed.

In the region forming step S410, the impurity region 140 and a second wafer 102 are adhered together. In this case, a surface of the first wafer 101, the surface being located on the opposite side of the impurity region 140, is referred to as a lower surface 23 of the semiconductor wafer 100. In addition, a surface of the second wafer 102, the surface being located on the opposite side of the surface which is adhered to the first wafer 101, is referred to as an upper surface 21 of the semiconductor wafer 100. Processes performed later than the region forming step S410 are similar to the examples described in FIG. 5 and FIG. 6.

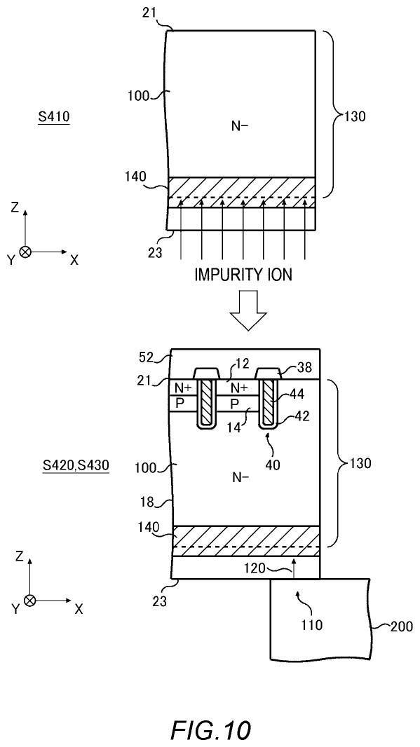

FIG. 10 illustrates another example of the region forming step S410, the upper surface side structure forming step S420, and the annealing step S430. In the present example, a part of the impurity region 140 is formed on the element region 130. The other points are similar to the example of FIG. 5.

As described above, in the region forming step S410 of the present example, a part of the impurity region 140 is formed on the element region 130, and the other portions are formed closer to the lower surface 23 side than the element region 130. In the upper surface side structure forming step S420, an upper surface side structure is formed, as in the example of FIG. 5. In addition, in the annealing step S430, a semiconductor wafer 100 is annealed, as in the example of FIG. 5.

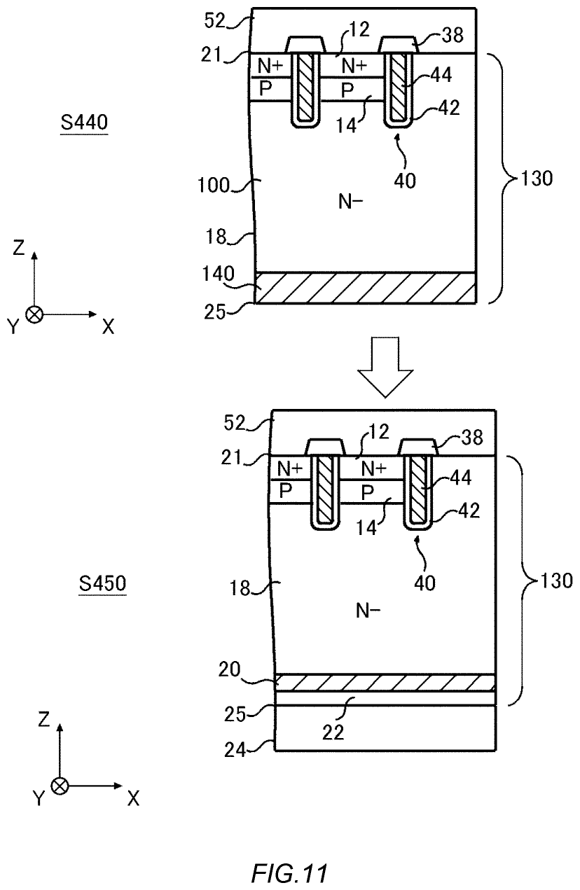

FIG. 11 illustrates another example of the removing step S440 and the lower surface side structure forming step S450. In the present example, a region including the lower surface 23 of the semiconductor wafer 100 is removed in the removing step S440 such that a part of the impurity region 140 remains. In the removing step S440, the impurity region 140 which is located below the element region 130 is removed.

In the lower surface side structure forming step S450, the remaining part of the impurity region 140 is used as an N type region of the semiconductor element. In the present example, the part of the remaining impurity region 140 is used as a buffer region 20. For example, if the first impurity is oxygen, by implanting hydrogen into the impurity region 140, hydrogen, oxygen and the defect can be combined and function as a donor. Accordingly, the buffer region 20 can be formed by implanting hydrogen into a region of the impurity region 140, which is close to the upper surface 21. In addition, by implanting an acceptor such as boron, a P type collector region 22 can be formed closer to the lower surface 25 side than the buffer region 20. In addition, if the semiconductor element is MOSFET, an N type drain region may be formed instead of the buffer region 20 and the collector region 22. By such a process, an N type region such as the buffer region 20 can be easily formed nearby the lower surface 25.

Note that an example of implanting the first impurity from the lower surface 23 of the semiconductor wafer 100 is described in FIG. 5 and the like. In another example, the first impurity may be implanted from the upper surface 21 of the semiconductor wafer 100. In addition, if the thickness of the element region 130 is small, the impurity region 140 may be formed on the upper surface 21 side of the semiconductor wafer 100.

While the embodiments of the present invention have been described, the technical scope of the invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the invention.

1. A semiconductor device manufacturing method comprising:
forming an impurity region including a first impurity on a semiconductor wafer;
annealing the semiconductor wafer in a state where a lower surface of the semiconductor wafer is supported; and
removing at least a part of the impurity region by removing a region including the lower surface of the semiconductor wafer.

2. The semiconductor device manufacturing method according to claim 1, wherein in the forming the impurity region, the impurity region is formed on an entire surface of the semiconductor wafer.

3. The semiconductor device manufacturing method according to claim 1, wherein the method comprises, between the forming the impurity region and the removing, forming at least a partial structure of a semiconductor element closer to an upper surface side than the impurity region.

4. The semiconductor device manufacturing method according to claim 1, wherein the first impurity is oxygen.

5. The semiconductor device manufacturing method according to claim 1, wherein after the annealing, a maximum value of a concentration of the first impurity in the impurity region is equal to or greater than 1×10¹⁸/cm³.

6. The semiconductor device manufacturing method according to claim 5, wherein after the annealing, a concentration of the first impurity in the impurity region is less than 1×10²⁰/cm³.

7. The semiconductor device manufacturing method according to claim 1, wherein in the forming the impurity region, the first impurity is implanted from the lower surface of the semiconductor wafer.

8. The semiconductor device manufacturing method according to claim 7, wherein in the forming the impurity region, the first impurity is implanted to a plurality of depth positions.

9. The semiconductor device manufacturing method according to claim 1, wherein in the forming the impurity region, the semiconductor wafer is formed by adhering a first wafer in which the impurity region is formed together with a second wafer.

10. The semiconductor device manufacturing method according to claim 1, wherein after the annealing, a width of the impurity region in a depth direction is equal to or less than 100 μm.

11. The semiconductor device manufacturing method according to claim 1, wherein the method comprises, after the removing, forming at least a partial structure of a semiconductor element on the lower surface side of the semiconductor wafer.

12. The semiconductor device manufacturing method according to claim 1, wherein in the removing, the entire impurity region is removed.

13. The semiconductor device manufacturing method according to claim 11, wherein
in the removing, a part of the impurity region remains, and
in the forming the lower surface side structure, the remaining part of the impurity region is used as an N type region of the semiconductor element.

14. The semiconductor device manufacturing method according to claim 1, wherein in the annealing, the semiconductor wafer is heated at a temperature equal to or greater than 1000° C.

15. The semiconductor device manufacturing method according to claim 1, wherein the impurity region is apart from an upper surface of the semiconductor wafer by equal to or greater than 400 μm.

16. The semiconductor device manufacturing method according to claim 2, wherein the method comprises, between the forming the impurity region and the removing, forming at least a partial structure of a semiconductor element closer to an upper surface side than the impurity region.

17. The semiconductor device manufacturing method according to claim 2, wherein the first impurity is oxygen.

18. The semiconductor device manufacturing method according to claim 3, wherein the first impurity is oxygen.

19. The semiconductor device manufacturing method according to claim 2, wherein after the annealing, a maximum value of a concentration of the first impurity in the impurity region is equal to or greater than 1×10¹⁸/cm³.

20. The semiconductor device manufacturing method according to claim 3, wherein after the annealing, a maximum value of a concentration of the first impurity in the impurity region is equal to or greater than 1×10¹⁸/cm³.
